(19) United States
(12) Patent Application Publication
(10) Pub. No.: US 2011/0024864 A1
(43) Pub. Date: Feb. 3, 2011

(54) SEMICONDUCTOR DEVICE AND METHOD FOR MANUFACTURING THE SAME

(75) Inventors: Noboru KOKUSENYA, Osaka (JP); Toshihiro KURIYAMA, Shiga (JP)

Correspondence Address: Michael E. Fogarty;MCDERMOTT WILL & EMERY LLP, 600 13th Street, N.W., Washington, DC, 20005-3096, US

(73) Assignee: PANASONIC CORPORATION, Osaka (JP)

(21) Appl. No.: 12/853,866

(22) Filed: Aug. 10, 2010

Related U.S. Application Data
(63) Continuation of application No. PCT/JP2009/001366, filed on Mar. 26, 2009.

(30) Foreign Application Priority Data
May 19, 2008 (JP) 2008-131246

(51) Int. Cl. H01L 27/14; H01L 23/48; H01L 23/532; H01L 31/0224

(52) U.S. Cl. 257/448; 257/768; 257/771; 257/741; 257/757; 257/762; 257/765; 257/773; 438/98; 257/E31.124; 257/E23.017; 257/E23.019; 257/E23.012; 257/E27.122

(57) ABSTRACT

A semiconductor device includes a through electrode penetrating a semiconductor substrate, a conductor pad formed on the through electrode and made of a conductor electrically connected to the through electrode, and an interconnection layer formed on a surface of the semiconductor substrate and electrically connected to the conductor pad.

### CROSS-REFERENCE TO RELATED APPLICATIONS

This is a continuation of PCT International Application PCT/JP2009/001366 filed on Mar. 26, 2009, which claims priority to Japanese Patent Application No. 2008-131246 filed on May 19, 2008. The disclosures of these applications including the specifications, the drawings, and the claims are hereby incorporated by reference in their entirety.

### BACKGROUND

The technology disclosed herein relates to semiconductor devices and methods for manufacturing the semiconductor devices, and more particularly, to the structure of a through electrode which allows smaller chips and packages to be provided.

In recent years, solid-state imaging devices, such as charge coupled devices (CCDs) and the like, have found increasing applications not only in camcorders, but also in digital cameras, mobile telephones, surveillance devices, medical devices, in-vehicle devices, and the like. As the range of applications increases, there is a stronger demand for a reduction in the system size, which also requires a reduction in the size of a CCD. Also, it is expected that the area (pixel area) of the photodetection surface of a photoelectric conversion device which is a photodetector which actually perform photoelectric conversion will be reduced and the number of photoelectric conversion devices arranged will also be reduced in order to provide a higher-performance CCD, and the chip size of the CCD will be reduced. However, the reduction in the chip size also requires an increase in the density of pixels and a reduction in the peripheral interconnection region, and in addition, a reduction in the package size.

For recent CCDs, a packaging technique called “wafer level chip scale packaging,” in which the interconnection step, the protective member attaching step, and the like are completed before the cleavage of a wafer into chips, may be employed in order to achieve a reduction in the size and an increase in the density. In general, in conventional CCDs to which the wafer level chip size packaging technique is applied, a flat transparent plate is provided above the photodetector of the imaging device. The transparent plate is joined to a wall surrounding the photodetector with an adhesive, whereby the photodetector including optical devices, such as a micro-lens and the like, is hermetically enclosed within a space formed by the wall and the transparent plate. Another structure in which the photodetector is enclosed with a protective plate made of glass or the like using an adhesive layer having a low refractive index which is formed immediately above the micro-lens, has been proposed in order to achieve a reduction in the size and an increase in the density. A key technique required for these size reducing techniques is to form an electrode (through electrode) which penetrates a wafer. The through electrode has a key role in reducing the size of a solid-state imaging device and improving the performance.

A conventional solid-state imaging device will be described hereinafter with reference to the accompanying drawings (see, for example, Japanese Patent Laid-Open Publication Nos. 2004-207461 and 2007-13061).

FIGS. 14A and 14B are diagrams showing a structure of the conventional solid-state imaging device. FIG. 14A is a schematic plan view and FIG. 14B is a schematic cross-sectional view taken along line XIVb-XIVb of FIG. 14A.

As shown in the plan view of FIG. 14A, a photodetector 102, and interconnects 103 and electrode pads 104 which are adjacent to the photodetector 102 and constitute an interconnection layer, are provided on a semiconductor chip 101. Through electrodes 105 are also provided which penetrate the semiconductor chip 101 and contact the electrode pads 104. Note that commonly used components, such as interconnects connected to the electrode pads 104 and the like, other than the aforementioned components are not shown for the sake of simplicity.

As shown in the cross-sectional view of FIG. 14B, the photodetector 102 is provided on a substrate 106. The interconnect 103 and the electrode pad 104 are formed on insulating films 107 and 108 formed on the substrate 106. The through electrode 105 penetrating the substrate 106 and the insulating films 107 and 108 is connected to the electrode pad 104 and a lower-surface electrode 109. An insulating film 110 for insulating the substrate 106 is formed between the through electrode 105, and the substrate 106 and the lower-surface electrode 109, and between the substrate 106, and the insulating film 107 and the photodetector 102.

According to the solid-state imaging device having the aforementioned structure, a drive pulse or an output signal can be applied to the device from the lower surface of the semiconductor substrate 101, and therefore, wire bonding is not required, whereby the size of the package as well as the size of the device itself can be reduced.

### SUMMARY

The aforementioned conventional structure has problems as follows. Firstly, there may be non-uniformity of the thickness of the substrate 106 which occurs when the entire substrate 106 is thinned, variations in the thickness of the insulating films 107 and 108 during the formation process, variations in a reduction in the thickness of the electrode pad 104 due to in-plane variations during the process of etching the electrode pad 104, and the like. Therefore, there are significant variations in the thickness of each of the layers including from the lower-surface electrode 109 provided on the lower surface of the substrate 106 to the electrode pad 104 provided on the upper surface of the substrate 106, which cause a problem when the hole in which the through electrode 105 is to be provided is formed.

Specifically, overetching is required in order to ensure contact with the electrode pad 104 provided on the upper surface of the substrate 106 by etching the substrate 106 made of silicon having a thickness of, for example, 100-300 nm or the insulating films 107 and 108 made of a silicon oxide film having a thickness of 500-2500 nm. However, because the upper-surface electrode pad 104 is formed of Al, Ti (10-100 nm), TiN (10-100 nm), or the like, a large etch selectivity ratio with respect to Si or SiO₂ cannot be obtained. Therefore, the overetching may cause problems, such as an increase in the resistance due to a decrease in the thickness of a portion of the upper-surface electrode pad 104, and the like, or in some cases, may form a hole penetrating the upper-surface electrode pad 104.

In view of the foregoing, the detailed description described implementations of a semiconductor device having a through electrode, which has a structure which can hinder or prevent the resistance increase or the penetration of the upper-surface interconnection layer, and a method for manufacturing the semiconductor device.

Semiconductor devices according to illustrative embodiments of the present disclosure and methods for manufacturing the semiconductor devices will be described hereinafter.

An example semiconductor device includes a through electrode penetrating a semiconductor substrate, a conductor pad formed on the through electrode and made of a conductor electrically connected to the through electrode, and an interconnection layer formed on a surface of the semiconductor substrate and electrically connected to the conductor pad.

In the example semiconductor device, the conductor pad is made of one selected from polysilicon, aluminum, metals containing aluminum, copper, copper alloys, refractory metals, and silicides thereof.

In the example semiconductor device, the conductor pad includes a plurality of layers each made of one selected from polysilicon, aluminum, metals containing aluminum, copper, copper alloys, refractory metals, and silicides thereof.

In the example semiconductor device, the interconnection layer and the conductor pad are connected to each other via a first contact plug.

In the example semiconductor device, the interconnection layer includes an electrode pad, a region of the interconnection layer in which the electrode pad is formed includes a region which a probe for probe testing contacts, and a region of the interconnection layer in which the electrode pad is not formed includes a region to which the first contact plug is connected.

In the example semiconductor device, the conductor pad includes a plurality of conductor pads electrically connected to each other, the lowest one of the plurality of conductor pads is electrically connected to the through electrode, and the uppermost one of the plurality of conductor pads is electrically connected to the interconnection layer.

In the example semiconductor device, the interconnection layer has a larger interconnect width than a diameter of the first contact plug.

In the example semiconductor device, the conductor pad has a larger area as viewed from the top than that of the through electrode.

In the example semiconductor device, of the plurality of conductor pads, adjacent ones partially overlap as viewed from the top and are electrically connected to each other via a second contact plug.

In the example semiconductor device, the through electrode is connected to the conductor pad directly or by the through electrode penetrating the conductor pad.

In the example semiconductor device, a plurality of photodetectors are formed on a surface of the semiconductor substrate.

In the example semiconductor device, the conductor pad is formed in the same layer in which a transfer electrode or an output transistor gate is formed.

In the example semiconductor device, there are a plurality of the through electrodes, and of the plurality of through electrodes, a distance between a first one connected to an output portion and a second one adjacent to the first one is larger than that between the other ones.

In the example semiconductor device, there are a plurality of the through electrodes, and of the plurality of through electrodes, an insulating film formed around a first one connected to an output portion has a larger thickness than that of an insulating film formed around each of the other ones.

In the example semiconductor device, there are a plurality of the through electrodes, and of the plurality of through electrodes, a first one connected to an output portion has a smaller area as viewed from the top than that of each of the other ones.

An example method for manufacturing a semiconductor device including a photodetector on an upper surface of a semiconductor substrate, includes the steps of (a) forming a conductor pad made of a conductor on the semiconductor substrate, (b) forming, on the upper surface of the semiconductor substrate, an interconnection layer electrically connected to the conductor pad, and (c) forming a through electrode penetrating a lower surface of the semiconductor substrate and electrically connected to the conductor pad.

The example method further includes the step of (d) between steps (a) and (b), forming an insulating film covering the conductor pad, and thereafter, forming a contact plug penetrating the insulating film and electrically connected to the conductor pad. Step (b) includes forming the interconnection layer including an electrode pad so that the interconnection layer is connected to the contact plug. A region of the interconnection layer in which the electrode pad is formed includes a region which a probe for probe testing contacts. A region of the interconnection layer in which the electrode pad is not formed includes a region to which the contact plug is connected.

In the example method, the through electrode is connected to the conductor pad directly or by the through electrode penetrating the conductor pad.

As described above, according to the present disclosure, in a semiconductor device having a through electrode, it is possible to hinder or prevent the resistance increase or the penetration of the upper-surface interconnection layer. As a result, a semiconductor device having high reliability can be manufactured.

### BRIEF DESCRIPTION OF THE DRAWINGS

FIG. 1A is a plan view schematically showing a structure of a solid-state imaging device which is a semiconductor device according to a first embodiment of the present disclosure.

FIG. 1B is a cross-sectional view schematically showing the structure of the solid-state imaging device, taken along line Ib-Ib of FIG. 1A.

FIG. 1C is a cross-sectional view schematically showing packaging of the solid-state imaging device.

FIG. 2A is a plan view schematically showing a structure of a solid-state imaging device which is a semiconductor device according to a second embodiment of the present disclosure.

FIG. 2B is a cross-sectional view schematically showing the structure of the solid-state imaging device, taken along line IIb-IIb of FIG. 2A.

FIG. 2C is a cross-sectional view similar to that of FIG. 2B, showing the structure in which an isolation region is formed.

FIG. 3A is a plan view schematically showing a structure of a solid-state imaging device which is a semiconductor device according to a third embodiment of the present disclosure.

FIG. 3B is a cross-sectional view schematically showing the structure of the solid-state imaging device, taken along line IIIb-IIIb of FIG. 3A.

FIG. 4A is a plan view schematically showing a structure of a solid-state imaging device which is a semiconductor device according to a variation of the third embodiment of the present disclosure.

FIG. 4B is a cross-sectional view schematically showing the structure of the solid-state imaging device, taken along line IVb-IVb of FIG. 4A.

FIG. 5A is a plan view schematically showing a structure of a solid-state imaging device which is a semiconductor device according to a fourth embodiment of the present disclosure.

FIG. 5B is a cross-sectional view schematically showing the structure of the solid-state imaging device, taken along line Vb-Vb of FIG. 5A.

FIG. 6A is a plan view schematically showing a structure of a solid-state imaging device which is a semiconductor device according to a variation of the fourth embodiment of the present disclosure.

FIG. 6B is a cross-sectional view schematically showing the structure of the solid-state imaging device, taken along line VIb-VIb of FIG. 6A.

FIG. 7A is a plan view schematically showing a structure of a solid-state imaging device which is a semiconductor device according to a fifth embodiment of the present disclosure.

FIG. 7B is a cross-sectional view schematically showing the structure of the solid-state imaging device, taken along line VIIb-VIIb of FIG. 7A.

FIG. 8A is a plan view schematically showing a structure of a solid-state imaging device which is a semiconductor device according to a sixth embodiment of the present disclosure.

FIG. 8B is a cross-sectional view schematically showing the structure of the solid-state imaging device, taken along line VIIb-VIIb of FIG. 8A.

FIG. 9A is a plan view schematically showing a structure of a solid-state imaging device which is a semiconductor device according to a variation of the sixth embodiment of the present disclosure.

FIG. 9B is a cross-sectional view schematically showing the structure of the solid-state imaging device, taken along line IXb-IXb of FIG. 9A.

FIG. 9C is a plan view showing an example in which the present disclosure is applied to the fifth and sixth embodiments.

FIG. 10A is a plan view schematically showing a structure of a solid-state imaging device which is a semiconductor device according to a seventh embodiment of the present disclosure.

FIG. 10B is a cross-sectional view schematically showing the structure of the solid-state imaging device, taken along line Xb-Xb of FIG. 10A.

FIG. 10C is a cross-sectional view schematically showing packaging of the solid-state imaging device.

FIGS. 11A-11D are cross-sectional views of main portions of a solid-state imaging device which is a semiconductor device according to an eighth embodiment of the present disclosure in the order in which the solid-state imaging device is manufactured.

FIGS. 12A-12D are cross-sectional views of main portions of the solid-state imaging device which is the semiconductor device of the eighth embodiment of the present disclosure in the order in which the solid-state imaging device is manufactured.

FIGS. 13A-13D are cross-sectional views of main portions of a solid-state imaging device which is a semiconductor device according to a ninth embodiment of the present disclosure in the order in which the solid-state imaging device is manufactured.

FIG. 14A is a plan view schematically showing a structure of a conventional solid-state imaging device.

FIG. 14B is a cross-sectional view schematically showing the structure of the conventional solid-state imaging device, taken along line XIVb-XIVb of FIG. 14A.

### DETAILED DESCRIPTION

Semiconductor devices according to illustrative embodiments of the present disclosure and methods for manufacturing the semiconductor devices will be described hereinafter. Here, as the example semiconductor devices, a solid-state imaging device, such as a CCD or the like, will be described. The present disclosure is not limited to the illustrative examples described below, and various modifications and changes can be made within the scope of the present disclosure.

### First Embodiment

A solid-state imaging device which is a semiconductor device according to a first embodiment of the present disclosure will be described with reference to the drawings.

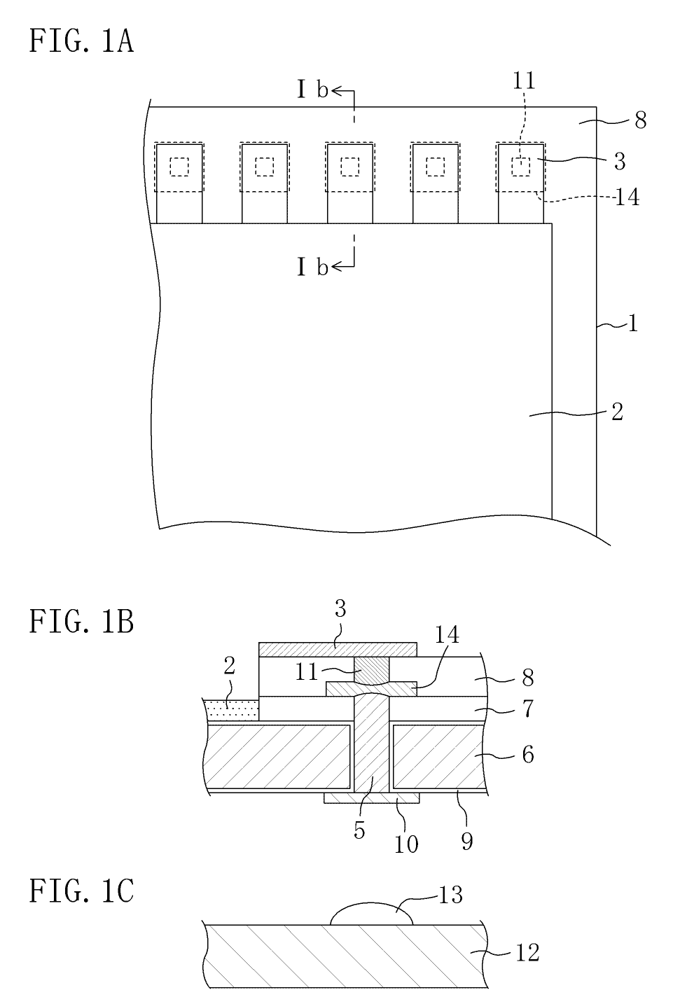

FIGS. 1A-1C are diagrams showing a structure of the solid-state imaging device of the first embodiment of the present disclosure. FIG. 1A is a schematic plan view, FIG. 1B is a schematic cross-sectional view taken along line Ib-Ib of FIG. 1A, and FIG. 1C is a schematic cross-sectional view showing example packaging.

As shown in the plan view of FIG. 1A, a photodetector 2, and interconnects 3 which are adjacent to the photodetector 2 and constitute an interconnection layer, are provided on a semiconductor chip 1. Also, as described below, through electrodes 5 are provided which penetrate the semiconductor chip 1 and are connected to the interconnects 3 via electrode pads 14 (conductor pads) and contact plugs 11. Note that commonly used components other than the aforementioned components are not shown for the sake of simplicity.

As shown in the cross-sectional view of FIG. 1B, the photodetector 2 is provided on a substrate 6. The interconnect 3 included in the interconnection layer is formed on insulating films 7 and 8 formed on the substrate 6. The through electrode 5 is formed to penetrate the substrate 6 and the insulating film 7. The through electrode 5 is connected to the electrode pad 14 formed on the insulating film 7. The electrode pad 14 is connected to the contact plug 11 formed in the insulating film 8. The contact plug 11 is connected to the interconnect 3 provided on the insulating film 8. The through electrode 5 is also connected to a lower-surface electrode 10 formed on the lower surface of the substrate 6. An insulating film 9 for insulating the substrate 6 is formed between the through electrode 5, and the substrate 6 and the lower-surface electrode 10, and between the substrate 6, and the insulating film 7 and the photodetector 2. Note that, as shown in FIG. 1B, the electrode pad 14 has a concave portion in a portion of each of the upper and lower surfaces thereof, which is hollowed by overetching when a through hole and a contact hole are formed.

The solid-state imaging device having the aforementioned structure is packaged by joining the lower-surface electrode 10 of FIG. 1A to a package 12 via a bump 13 which is formed on the package 12, for example, as shown in FIG. 1C.

As described above, the structure of the solid-state imaging device of the first embodiment of the present disclosure is different from that of the aforementioned conventional solid-state imaging device in that the contact plug 11 is formed in a region below the interconnect 3, and the interconnect 3 and the lower-surface electrode 10 are connected to each other via the electrode pad 14 and the contact plug 11 in addition to the through electrode 5. Therefore, according to the solid-state imaging device of this embodiment, a through hole for forming the through electrode 5 may be formed only in the substrate 6 and the insulating film 7, resulting in a higher manufacturing throughput than that of the conventional example. Moreover, when the electrode pad 14 is made of polysilicon (p-Si), a sufficient etching selectivity ratio with respect to the insulating film 7 made of silicon oxide or the like can be ensured. Therefore, even when overetching is performed in order to form the through hole, it is possible to hinder or prevent the electrode pad 14 made of p-Si from being partially thinned to increase the resistance and from being penetrated to cause a defect. Note that the electrode pad 14 may include one or more layers each of which is made of one selected from polysilicon, aluminum, metals containing aluminum, copper, copper alloys, refractory metals, and silicides thereof.

### Second Embodiment

A solid-state imaging device which is a semiconductor device according to a second embodiment of the present disclosure will be described hereinafter with reference to the drawings.

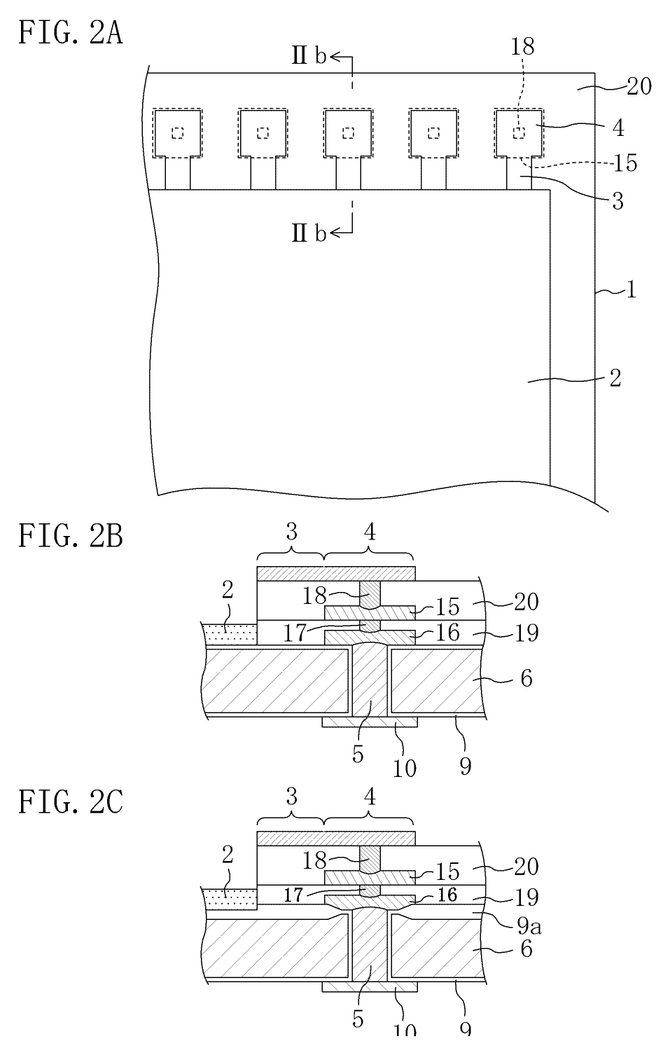

FIGS. 2A-2C are diagrams showing a structure of the solid-state imaging device of the second embodiment of the present disclosure. FIG. 2A is a schematic plan view, FIG. 2B is a schematic cross-sectional view taken along line IIb-IIb of FIG. 2A, and FIG. 2C is a cross-sectional view similar to that of FIG. 2B, showing the structure in which an isolation region is formed.

As shown in the plan view of FIG. 2A, a photodetector 2, and interconnects 3 and electrode pads 4 which are adjacent to the photodetector 2 and constitute an interconnection layer, are provided on a semiconductor chip 1. Also, as described below, through electrodes 5 are provided which penetrate the semiconductor chip 1 and are connected to the electrode pads 4 via through electrode pads 15 (conductor pads), electrode pads 16 (conductor pads), and contact plugs 17 and 18. Note that commonly used components other than the aforementioned components are not shown for the sake of simplicity.

As shown in the cross-sectional view of FIG. 2B, the photodetector 2 is provided on a substrate 6. The interconnect 3 and the electrode pad 4 which constitute the interconnection layer are formed on insulating films 19 and 20 formed on the substrate 6. The through electrode 5 is formed to penetrate the substrate 6. The through electrode 5 is connected to the electrode pad 16 formed on the substrate 6. The electrode pad 16 is connected to the contact plug 17 formed in the insulating film 19. The contact plug 17 is connected to the electrode pad 15 formed on the insulating film 19. The electrode pad 15 is connected to the contact plug 18 formed in the insulating film 20. The contact plug 18 is connected to the electrode pad 4 formed on the insulating film 20. The through electrode 5 is also connected to a lower-surface electrode 10 formed on the lower surface of the substrate 6. An insulating film 9 for insulating the substrate 6 is formed between the through electrode 5, and the substrate 6 and the lower-surface electrode 10, and between the substrate 6, and the insulating film 19 and the photodetector 2. Note that, in FIG. 2B, the electrode pad 16 has a concave portion in a portion of each of the upper and lower surfaces thereof, and the electrode pad 15 has a concave portion in a portion of the upper surface thereof. The concave portions are hollowed by overetching when a through hole and a contact hole are formed.

Although FIG. 2B shows a structure in which the electrode pad 16 is formed in a region in which the isolation region, such as LOCOS or shallow trench isolation (STI), is not formed, an isolation region 9a, such as LOCOS or STI, may be formed in a region other than that which is connected to the through electrode 5, for example, as shown in FIG. 2C. Specifically, an insulating film having a thickness of as small as 15-100 nm may be provided between the substrate 6 and the electrode pad 16.

As described above, in the solid-state imaging device of the second embodiment of the present disclosure, the contact plugs 17 and 18 and the electrode pads 15 and 16 are formed in a region below the electrode pad 4. Thus, the interconnect 3 and the lower-surface electrode 10 are connected to each other via a plurality of conductors, i.e., the through electrode 5, and in addition, the electrode pads 15 and 16 and the contact plugs 17 and 18. Therefore, according to the solid-state imaging device of this embodiment, a through hole for forming the through electrode 5 may be formed only in the substrate 6, whereby a higher manufacturing throughput than that of the conventional example can be obtained. Moreover, when the electrode pad 16 is made of polysilicon (p-Si), it is possible to hinder or prevent the electrode pad 16 from being partially thinned to increase the resistance and from being penetrated to cause a defect.

The insulating film 19 may be made of HTO, a polysilicon oxide film, tetraethyl orthosilicate or tetraethoxysilane (TEOS), or other deposited materials obtained by chemical vapor deposition (CVD). Moreover, when the electrode pad 15 is made of a refractory metal, such as tungsten (W) or the like, or a silicide thereof, the formation of the electrode pad 15 or the contact hole does not require a large number of additional steps. Note that the electrode pads 15 and 16 may include one or more layers each of which is made of one selected from polysilicon, aluminum, metals containing aluminum, copper, copper alloys, refractory metals, and silicides thereof.

### Third Embodiment

A solid-state imaging device which is a semiconductor device according to a third embodiment of the present disclosure will be described hereinafter with reference to the drawings.

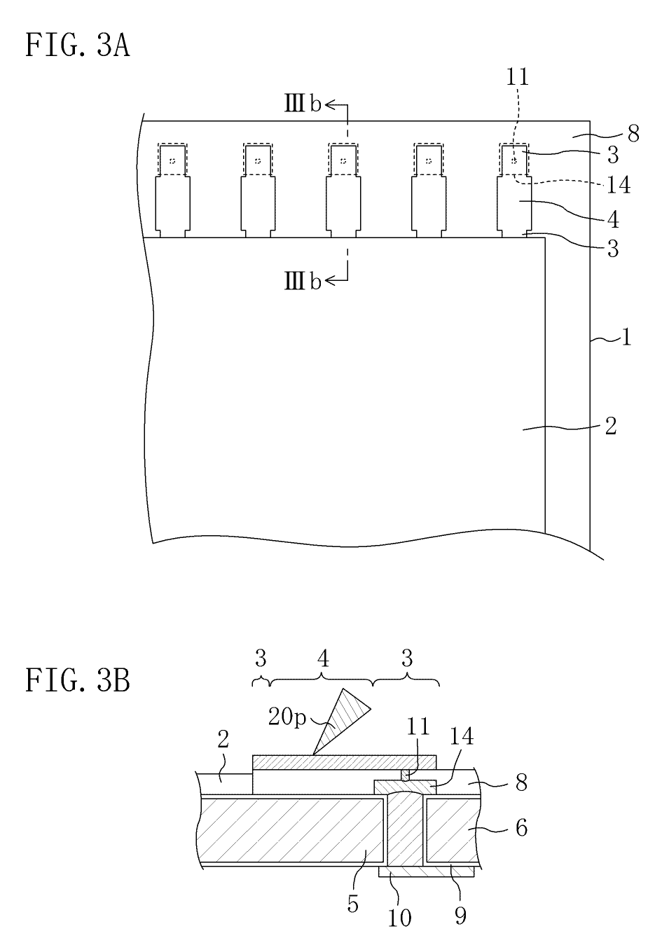

FIGS. 3A and 3B are diagrams showing a structure of the solid-state imaging device of the third embodiment of the present disclosure. FIG. 3A is a schematic plan view and FIG. 3B is a schematic cross-sectional view taken along line IIIb-IIIb of FIG. 3A.

As shown in the plan view of FIG. 3A, a photodetector 2, and interconnects 3 and electrode pads 4 which are adjacent to the photodetector 2 and constitute an interconnection layer, are provided on a semiconductor chip 1. Also, as described below, through electrodes 5 are provided which penetrate the semiconductor chip 1 and are connected to the interconnects 3 via electrode pads 14 (conductor pads) and contact plugs 11. Note that commonly used components other than the aforementioned components are not shown for the sake of simplicity.

As shown in the cross-sectional view of FIG. 3B, the photodetector 2 is provided on a substrate 6. The interconnect 3 and the electrode pad 4 which constitute the interconnection layer are formed on an insulating film 8 formed on the substrate 6. The through electrode 5 is formed to penetrate the substrate 6. The through electrode 5 is connected to the electrode pad 4 formed on the insulating film 8. The electrode pad 4 is connected to a contact plug 11 formed in the insulating film 8. The contact plug 11 is connected to the interconnect 3 formed on the insulating film 8. The electrode pad 5 is also connected to a lower-surface electrode 10 formed on the lower surface of the substrate 6. An insulating film 9 for insulating the substrate 6 is formed between the through electrode 5, and the substrate 6 and the lower-surface electrode 10, and between the substrate 6, and the insulating film 8 and the photodetector 2. Note that, in FIG. 3B, the electrode pad 14 has a concave portion in a portion of each of the upper and lower surfaces thereof, which is hollowed by overetching when a through hole and a contact hole are formed. In this cross-section, a single layer of electrode pads is formed in an insulating film, and another insulating film having a thinner thickness is provided below the electrode pads. The present disclosure is not limited to this example. Alternatively, as shown in FIGS. 1B, 2B, and 2C, a plurality of layers of electrode pads or a plurality of insulating films may be formed, or a device formation region, such as LOCOS or the like, may be provided between the electrode pad and the substrate. Note that the electrode pad 14 may include one or more layers each of which is made of one selected from polysilicon, aluminum, metals containing aluminum, copper, copper alloys, refractory metals, and silicides thereof.

Here, as shown in FIGS. 3A and 3B, the interconnect 3 is formed to extend from the photodetector 2. In the vicinity of the terminal end of the interconnect 3, the contact plug 11 electrically connected to the electrode pad 14 provided below the interconnect 3 is formed. The electrode pad 4 having a larger width than that of the interconnect 3 is formed in a region which is closer to the photodetector 2 than the terminal end of the interconnect 3 which is connected to the contact plug 11. To this region, a probe 20p is caused to contact during probe testing.

According to the solid-state imaging device of the third embodiment of the present disclosure having the aforementioned structure, firstly, a manufacturing throughput with which the formation of the through electrode 5 is involved can be increased, and it is possible to hinder or prevent the electrode pad 14 from having an increased resistance and from being penetrated to cause a defect, as in the first and second embodiments. Moreover, when the diffusion step is completed or when the formation of the on-chip filter is completed, probe testing can be performed to determine whether or not the performance of each chip is good. Because the region which the probe 20p contacts is separated from the region in which the contact plug 11 connected to the electrode pad 14 is formed, it is possible to hinder or prevent the probe 20p from contacting the contact plug 11 to cause a defect.

Variation—

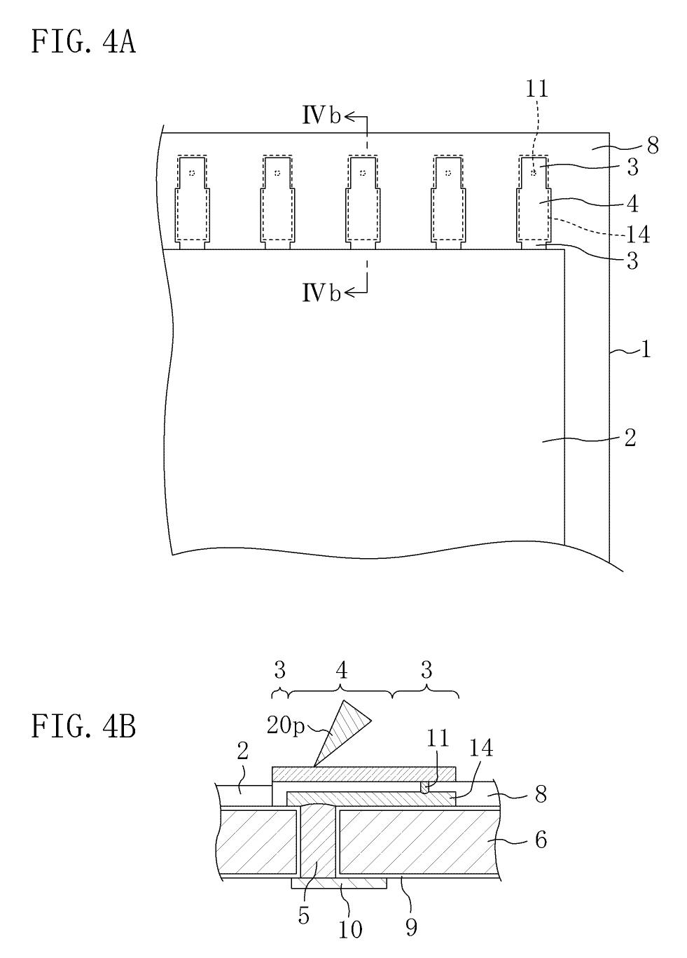

FIGS. 4A and 4B are diagrams showing a structure of a solid-state imaging device which is a semiconductor device according to a variation of the third embodiment of the present disclosure. FIG. 4A is a schematic plan view and FIG. 4B is a schematic cross-sectional view taken along line IVb-IVb of FIG. 4A.

In the structure of FIGS. 4A and 4B, a through electrode 5 is not formed in a region immediately below a contact plug 11, and therefore, an electrode pad 14 is formed to extend from a region immediately below the contact plug 11 to the vicinity immediately above the through electrode 5. In this case, the flexibility of the arrangement of a lower-surface electrode 10 can be increased.

### Fourth Embodiment

A solid-state imaging device which is a semiconductor device according to a fourth embodiment of the present disclosure will be described hereinafter with reference to the drawings.

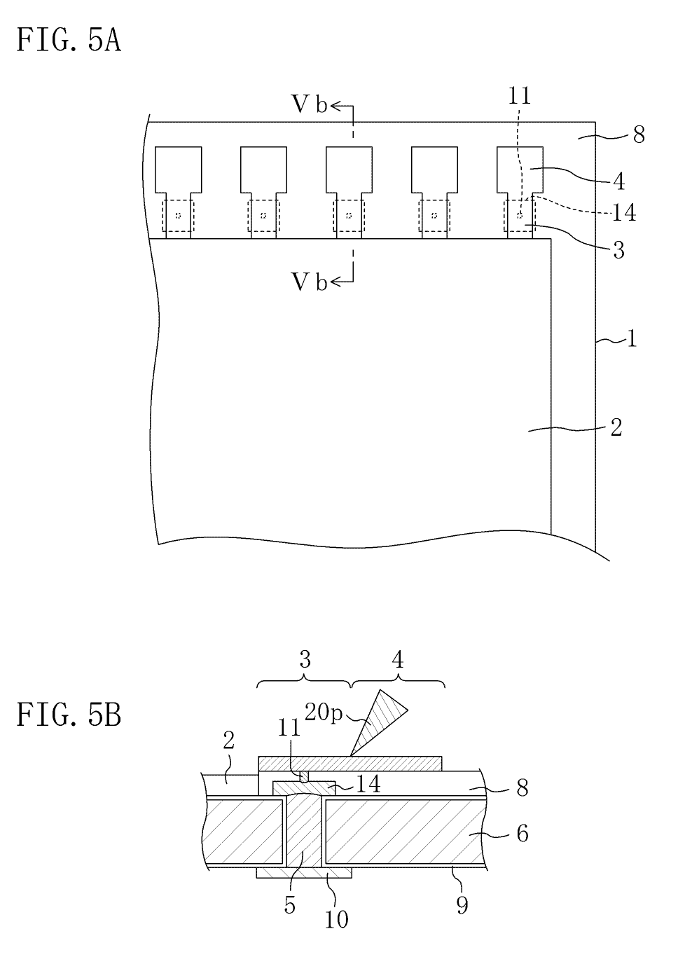

FIGS. 5A and 5B are diagrams showing a structure of the solid-state imaging device of the fourth embodiment of the present disclosure. FIG. 5A is a schematic plan view and FIG. 5B is a schematic cross-sectional view taken along line Vb-Vb of FIG. 5A.

As shown in the plan view of FIG. 5A, a photodetector 2, and interconnects 3 and electrode pads 4 which are adjacent to the photodetector 2 and constitute an interconnection layer, are provided on a semiconductor chip 1. Also, as described below, through electrodes 5 are provided which penetrate the semiconductor chip 1 and are connected to the interconnects 3 via electrode pads 14 (conductor pads) and contact plugs 11. Note that commonly used components other than the aforementioned components are not shown for the sake of simplicity.

As shown in the cross-sectional view of FIG. 5B, the photodetector 2 is provided on a substrate 6. The interconnect 3 and the electrode pad 4 which constitute the interconnection layer are formed on an insulating film 8 formed on the substrate 6. The through electrode 5 is formed to penetrate the substrate 6. The through electrode 5 is connected to the electrode pad 4 formed on the insulating film 8. The electrode pad 4 is connected to a contact plug 11 formed in the insulating film 8. The contact plug 11 is connected to the interconnect 3 formed on the insulating film 8. The electrode pad 5 is also connected to a lower-surface electrode 10 formed on the lower surface of the substrate 6. An insulating film 9 for insulating the substrate 6 is formed between the through electrode 5, and the substrate 6 and the lower-surface electrode 10, and between the substrate 6, and the insulating film 8 and the photodetector 2. Note that, in FIG. 5B, the electrode pad 14 has a concave portion in a portion of each of the upper and lower surfaces thereof, which is hollowed by overetching when a through hole and a contact hole are formed. In this cross-section, a single layer of electrode pads is formed in an insulating film, and another insulating film having a thinner thickness is provided below the electrode pads. The present disclosure is not limited to this example. Alternatively, as shown in FIGS. 1B, 2B, and 2C, a plurality of layers of electrode pads or a plurality of insulating films may be formed, or a device formation region, such as LOCOS or the like, may be provided between the electrode pad and the substrate. Note that the electrode pad 14 may include one or more layers each of which is made of one selected from polysilicon, aluminum, metals containing aluminum, copper, copper alloys, refractory metals, and silicides thereof.

Here, as shown in FIGS. 5A and 5B, the interconnect 3 is formed to extend from the photodetector 2, and the contact plug 11 electrically connected to the electrode pad 14 is formed below the interconnect 3. The electrode pad 4 having a larger width than that of the interconnect 3 is formed in the vicinity of the terminal end of the interconnect 3 which is connected to the contact plug 11. A probe 20p is caused to contact the electrode pad 4 during probe testing.

According to the solid-state imaging device of the fourth embodiment of the present disclosure having the aforementioned structure, firstly, a manufacturing throughput with which the formation of the through electrode 5 is involved can be increased, and it is possible to hinder or prevent the electrode pad 14 from having an increased resistance and from being penetrated, as in the first and second embodiments. Moreover, when the diffusion step is completed or when the formation of the on-chip filter is completed, probe testing can be performed to determine whether or not the performance of each chip is good. Because the region which the probe 20p contacts is separated from the region in which the contact plug 11 connected to the electrode pad 14 is formed, it is possible to hinder or prevent the probe 20p from contacting the contact plug 11 to cause a defect.
Variation—

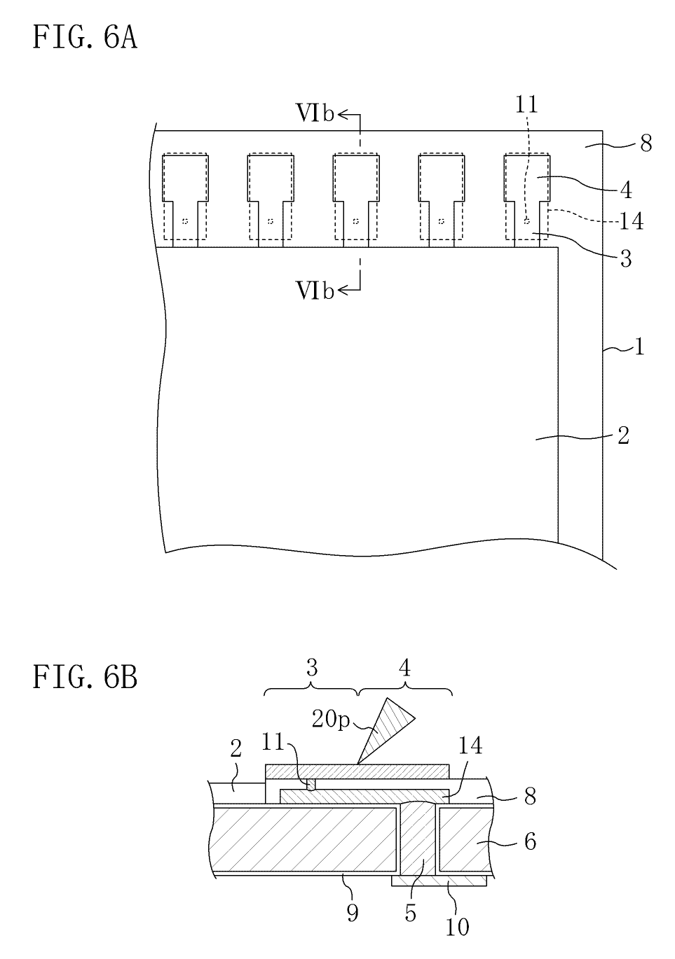

FIGS. 6A and 6B are diagrams showing a structure of a solid-state imaging device which is a semiconductor device according to a variation of the fourth embodiment of the present disclosure. FIG. 6A is a schematic plan view and FIG. 6B is a schematic cross-sectional view taken along line VIb-VIb of FIG. 6A.

In the structure of FIGS. 6A and 6B, a through electrode 5 is not formed in a region immediately below a contact plug 11, and therefore, an electrode pad 14 is formed to extend from a region immediately below the contact plug 11 to the vicinity immediately above the through electrode 5. In this case, the flexibility of the arrangement of a lower-surface electrode 10 can be increased.

### Fifth Embodiment

A solid-state imaging device which is a semiconductor device according to a fifth embodiment of the present disclosure will be described hereinafter with reference to the drawings.

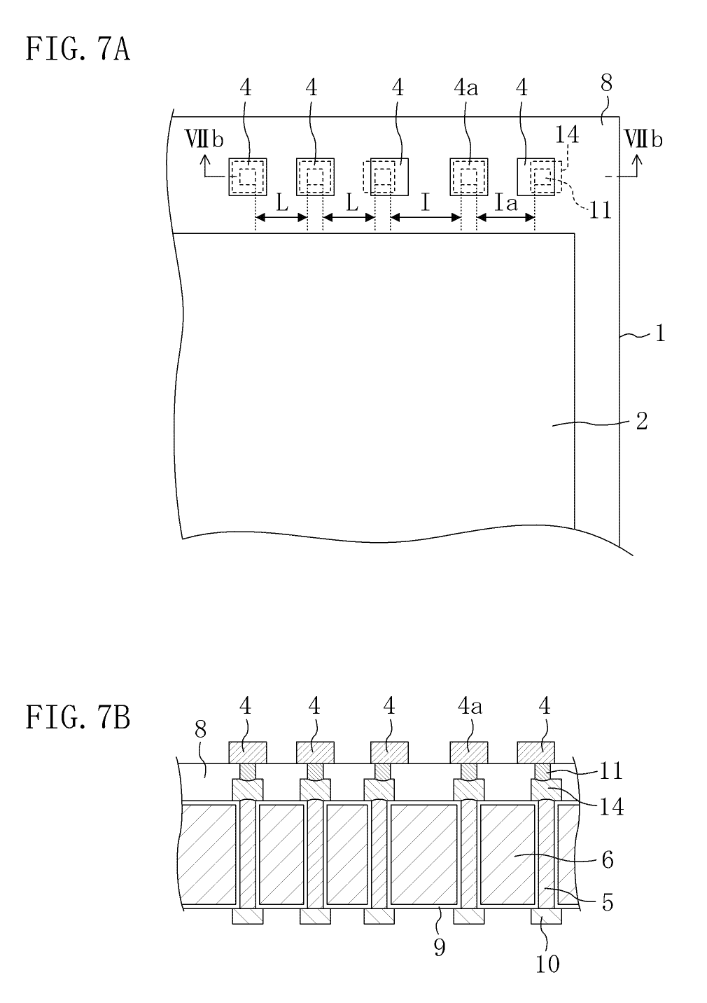

FIGS. 7A and 7B are diagrams showing a structure of the solid-state imaging device of the fifth embodiment of the present disclosure. FIG. 7A is a schematic plan view and FIG. 7B is a schematic cross-sectional view taken along line VIIb-VIIb of FIG. 7A.

As shown in the plan view of FIG. 7A, a photodetector 2 and electrode pads 4 are provided on a semiconductor chip 1. The electrode pads 4 are located away from the photodetector 2 with interconnects (not shown) which constitute an interconnection layer being interposed therebetween. Also, as described below, through electrodes 5 are provided which penetrate the semiconductor chip 1 and are connected to the electrode pads 4 via electrode pads 14 (conductor pads) and contact plugs 11. Note that the contact plugs 11 are disposed at intervals of L. Note that commonly used components other than the aforementioned components are not shown for the sake of simplicity.

As shown in the cross-sectional view of FIG. 7B, the electrode pads 4 and electronic pads 4a which constitute the interconnection layer are formed on an insulating film 8 formed on a substrate 6. The through electrodes 5 are formed to penetrate the substrate 6 and are connected to the electrode pads 4 and 4a formed on the insulating film 8 via the contact plugs 11 formed in the insulating film 8. The electrode pads 5 are also connected to lower-surface electrodes 10 formed on the lower surface of the substrate 6. An insulating film 9 for insulating the substrate 6 is formed between the through electrode 5, and the substrate 6 and the lower-surface electrodes 10, and between the substrate 6 and the insulating film 8. Note that, in FIG. 7B, each electrode pad 14 has a concave portion in a portion of each of the upper and lower surfaces thereof, which is hollowed by overetching when a through hole and a contact hole are formed. In this cross-section, a single layer of electrode pads is formed in an insulating film, and another insulating film having a thinner thickness is provided below the electrode pads. The present disclosure is not limited to this example. Alternatively, as shown in FIGS. 1B, 2B, and 2C, a plurality of layers of electrode pads or a plurality of insulating films may be formed, or a device formation region, such as LOCOS or the like, may be provided between the electrode pad and the substrate. Note that the electrode pad 14 may include one or more layers each of which is made of one selected from polysilicon, aluminum, metals containing aluminum, copper, copper alloys, refractory metals, and silicides thereof.

Here, as shown in FIGS. 7A and 7B, the contact plug 11 is formed to connect to substantially a center portion of the electrode pad 4a which is an output portion, and is also connected to the electrode pad 14 therebelow. The through electrode 5 is formed below the electrode pad 14 and is connected to the lower-surface electrode 10. On the other hand, for the electrode pads 4 provided on the opposite sides of the electrode pad 4a which is an output portion, the contact plug 11 is formed at a position offset from the center of the electrode pad 4 in a direction away from the electrode pad 4a which is an output portion, and is connected to the electrode pad 14 therebelow. The through electrode 5 connected to the electrode pad 14 is also each formed at a position offset from the center of the electrode pad 4 in a direction away from the through electrode 5 electrically connected to the electrode pad 4a which is an output portion. Specifically, the contact plugs 11 may be formed so that distances L, I, and Ia between the contact plugs 11 shown in FIGS. 7A and 7B satisfy a relationship L<I and Ia<I. Although an example has been described in FIGS. 7A and 7B that both the contact plug 11 and the through electrode 5 have the aforementioned structure, either one of the contact plug 11 and the through electrode 5 may have the aforementioned structure.

According to the solid-state imaging device of the fifth embodiment of the present disclosure having the aforementioned structure, the contact plug 11 and the through electrode 5 connected to the output portion are located at an increased distance from the through electrodes 5 to which a drive pulse for the solid-state imaging device is applied, and therefore, are less affected by the drive pulse. As a result, the drive pulse is hindered or prevented from being mixed into an output signal, whereby signal noise can be reduced, the circuit can be more easily controlled, and the like, i.e., the image quality can be improved.

### Sixth Embodiment

A solid-state imaging device which is a semiconductor device according to a sixth embodiment of the present disclosure will be described hereinafter with reference to the drawings.

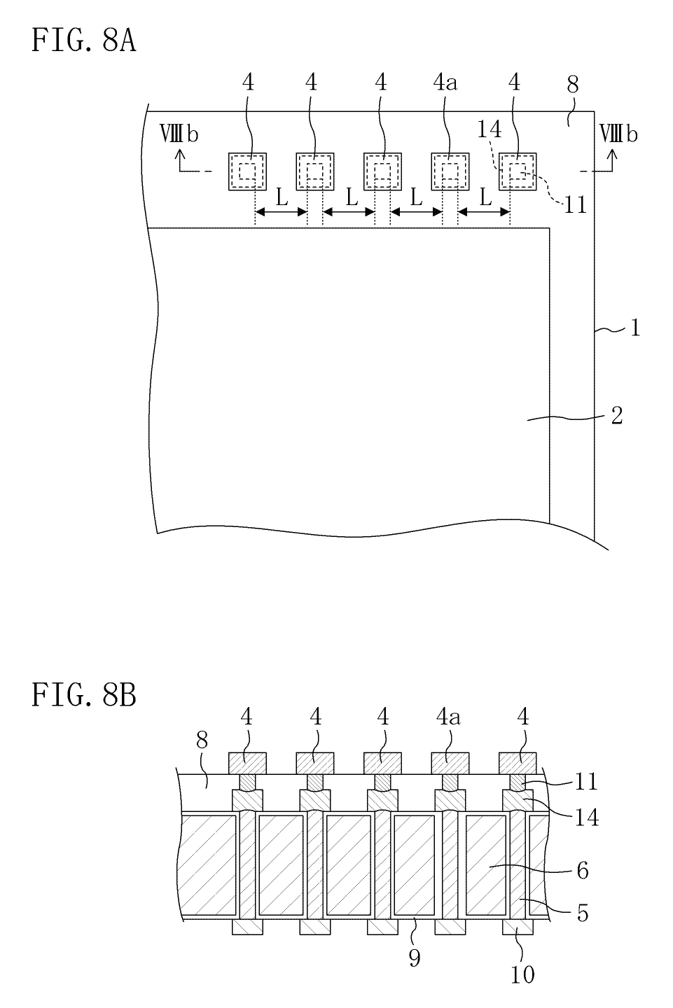

FIGS. 8A and 8B are diagrams showing a structure of the solid-state imaging device of the sixth embodiment of the present disclosure. FIG. 8A is a schematic plan view and FIG. 8B is a schematic cross-sectional view taken along line VIIIb-VIIIb of FIG. 8A.

As shown in the plan view of FIG. 8A, a photodetector 2 and electrode pads 4 are provided on a semiconductor chip 1. The electrode pads 4 are located away from the photodetector 2 with interconnects (not shown) which constitute an interconnection layer being interposed therebetween. Also, as described below, through electrodes 5 are provided which penetrate the semiconductor chip 1 and are connected to the electrode pads 4 via electrode pads 14 (conductor pads) and contact plugs 11. Note that the contact plugs 11 are disposed at intervals of L. Note that commonly used components other than the aforementioned components are not shown for the sake of simplicity.

As shown in the cross-sectional view of FIG. 8B, the electrode pads 4 and electronic pads 4a which constitute the interconnection layer are formed on an insulating film 8 formed on a substrate 6. The through electrodes 5 are formed to penetrate the substrate 6. The through electrodes 5 are connected to the electrode pads 4 and 4a formed on the insulating film 8 via the contact plugs 11 formed in the insulating film 8. The electrode pads 5 are also connected to lower-surface electrodes 10 formed on the lower surface of the substrate 6. An insulating film 9 for insulating the substrate 6 is formed between the through electrode 5, and the substrate 6 and the lower-surface electrodes 10, and between the substrate 6 and the insulating film 8. Note that, in FIG. 8B, each electrode pad 14 has a concave portion in a portion of each of the upper and lower surfaces thereof, which is hollowed by overetching when a through hole and a contact hole are formed. In this cross-section, a single layer of electrode pads is formed in an insulating film, and another insulating film having a thinner thickness is provided below the electrode pads. The present disclosure is not limited to this example. Alternatively, as shown in FIGS. 1B, 2B, and 2C, a plurality of layers of electrode pads or a plurality of insulating films may be formed, or a device formation region, such as LOCOS or the like, may be provided between the electrode pad and the substrate. Note that the electrode pad 14 may include one or more layers each of which is made of one selected from polysilicon, aluminum, metals containing aluminum, copper, copper alloys, refractory metals, and silicides thereof.

Here, as shown in FIGS. 8A and 8B, a through electrode 5 is formed for the electrode pad 4a which is an output portion with a contact plug 11 and an electrode pad 14 being interposed therebetween. The insulating film 9 provided around that through electrode 5 has a larger thickness than that of the insulating film 9 around the other through electrodes 5.

According to the solid-state imaging device of the sixth embodiment of the present disclosure having the aforementioned structure, the physical distance between the through electrode 5 electrically connected to the electrode pad 4a which is an output portion and the substrate 6 is increased, resulting in a smaller parasitic capacitance, whereby the image quality can be improved.

Variation—

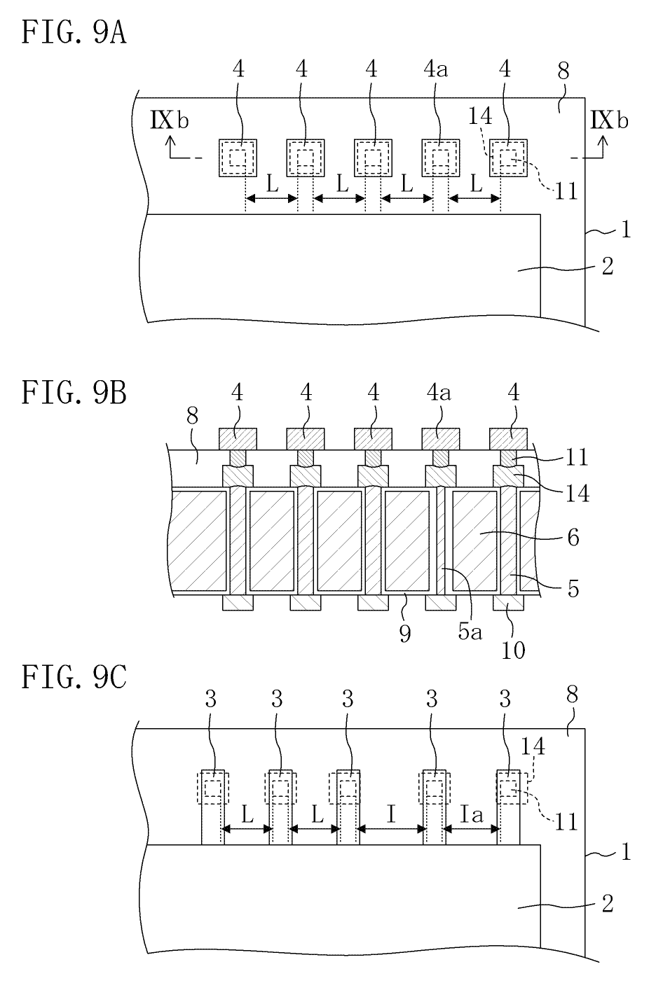

FIGS. 9A and 9B are diagrams showing a structure of a solid-state imaging device which is a semiconductor device according to a variation of the sixth embodiment of the present disclosure. FIG. 9A is a schematic plan view and FIG. 9B is a schematic cross-sectional view taken along line IXb-IXb of FIG. 9A.

In the structure of FIGS. 9A and 9B, contact plugs 11 are equally spaced as in the foregoing examples, and in addition, a through electrode 5a electrically connected to an electrode pad 4a which is an output portion has a smaller cross-sectional area than that of other through electrodes 5b.

In this case, the physical distance between the through electrode 5a and a substrate 6 is increased as in the foregoing examples, resulting in a smaller parasitic capacitance, whereby the image quality can be improved.

Note that, in the fifth and sixth embodiments, examples have been described in which the electrode pads 4 connected to the interconnects (not shown) are provided. However, as shown in FIG. 9C showing a structure corresponding to that of FIG. 7A, only interconnects 3 extending from a photodetector 2 may be provided without providing electrode pads 4.

### Seventh Embodiment

A solid-state imaging device which is a semiconductor device according to a seventh embodiment of the present disclosure will be described hereinafter with reference to the drawings.

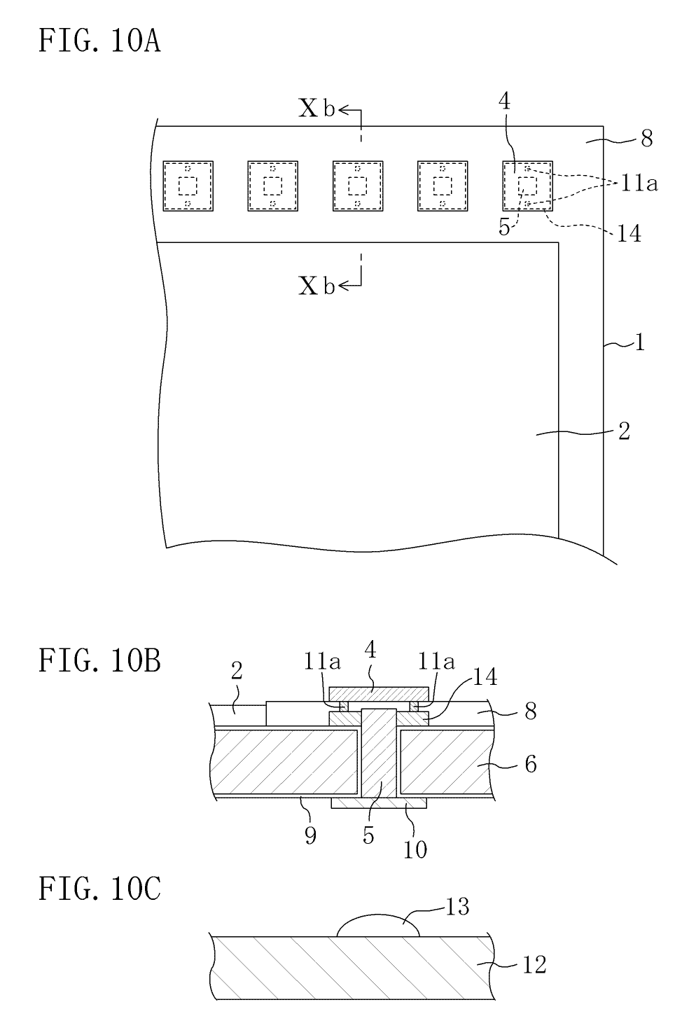

FIGS. 10A-10C are diagrams showing a structure of the solid-state imaging device of the seventh embodiment of the present disclosure. FIG. 10A is a schematic plan view, FIG. 10B is a schematic cross-sectional view taken along line Xb-Xb of FIG. 10A, and FIG. 10C is a schematic cross-sectional view showing example packaging.

In the plan view of FIG. 10A, a photodetector 2, and electrode pads 4 connected to interconnects (not shown) connected to transfer electrodes or output portions (not shown) of the photodetector 2, are provided on a semiconductor chip 1. Also, as described below, through electrodes 5 are provided which penetrate the semiconductor chip 1 and are connected to the electrode pads 4 via electrode pads 14 (conductor pads) and contact plugs 11a. Here, the electrode pads 14 are made of, for example, polysilicon. The through electrodes 5 penetrate substantially the centers of the electrode pads 14. For each electrode pad 4, a plurality of contact plugs 11a are formed which penetrate the insulating film 8 in a peripheral portion of the electrode pad 14 and are connected to the electrode pad 4. Note that commonly used components other than the aforementioned components are not shown for the sake of simplicity.

As shown in the cross-sectional view of FIG. 10B, the photodetector 2 is provided on a substrate 6. The electrode pad 4 which constitutes the interconnection layer is formed on the insulating film 8 formed on the substrate 6. The through electrode 5 is formed to penetrate the substrate 6. The through electrode 5 penetrates substantially the center of the electrode pad 14 made of, for example, polysilicon. The electrode pad 14 is connected to the contact plugs 11a formed in the insulating film 8. The contact plugs 11a are connected to the electrode pad 4 formed on the insulating film 8. The electrode pad 5 is also connected to a lower-surface electrode 10 formed on the lower surface of the substrate 6. An insulating film 9 for insulating the substrate 6 is formed between the through electrode 5, and the substrate 6 and the lower-surface electrode 10, and between the substrate 6, and the insulating film 8 and the photodetector 2.

The solid-state imaging device having the aforementioned structure is packaged by joining the lower-surface electrode 10 of FIG. 10A to a package 12 via a bump 13 which is formed on the package 12, for example, as shown in FIG. 10C.

Here, in the aforementioned structure, when a through hole for the formation of the through electrode 5 is formed by etching, overetching needs to be performed to a greater extent. In this case, the through hole may be likely to enter or penetrate the electrode pad 14 made of polysilicon. In fact, because the insulating film 8, which is an oxide film, is provided above the electrode pad 14 made of polysilicon, etching is halted by the insulating film 8.

According to the solid-state imaging device of the seventh embodiment of the present disclosure having the aforementioned structure, the through electrode 5 and the electrode pad 14 made of polysilicon contact each other at a side surface of the electrode pad 14, whereby an increase in the resistance can be reduced. Moreover, when the through hole is directly provided in the electrode pad 14 made of Al or the like, the through hole penetrates and reaches the insulating film 8 provided on the electrode pad 14 because of the small selectivity ratio of Al to the oxide film, resulting in a decrease in the reliability. In this embodiment, as described above, because the electrode pad 14 is made of polysilicon, such a decrease in the reliability can be reduced.

Although an example has been described in this embodiment that the electrode pads 4 connected to the interconnects (not shown) are provided, only interconnects 3 extending from the photodetector 2 may be provided without providing the electrode pads 4.

Moreover, only one of the contact plugs 11a may be provided, and a through electrode 5 may be provided instead of the other contact plug 11a.

### Eighth Embodiment

A method for manufacturing a solid-state imaging device which is a method for manufacturing a semiconductor device according to an eighth embodiment of the present disclosure will be described hereinafter with reference to the drawings.

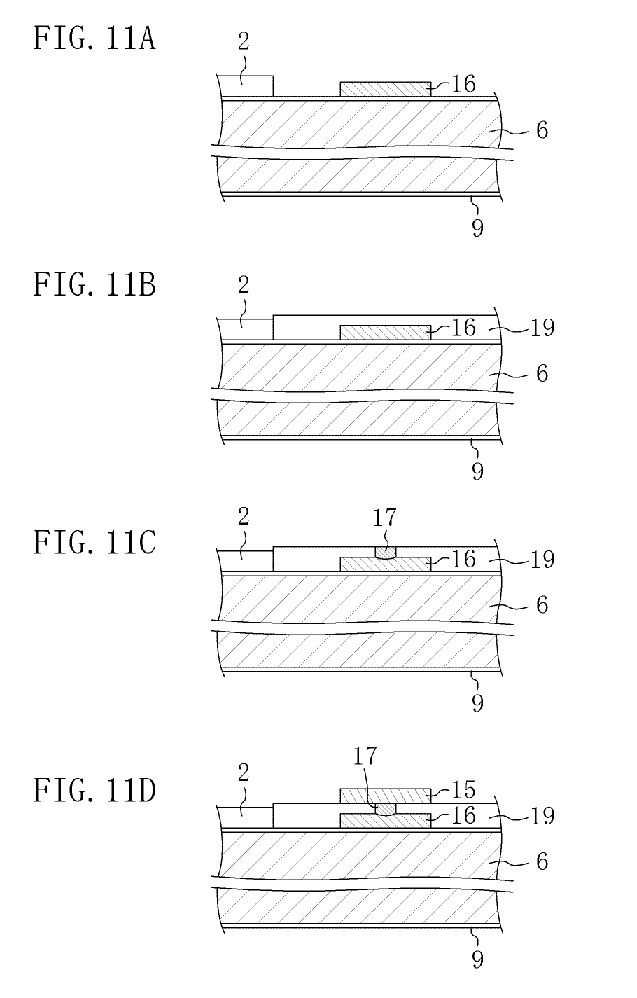

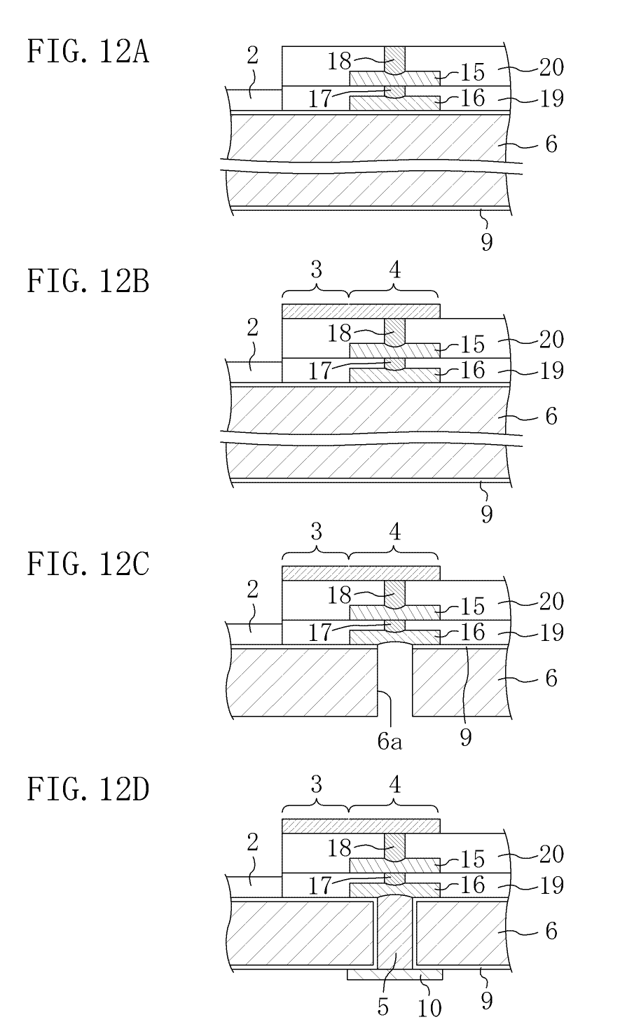

FIGS. 11A-11D and 12A-12D are cross-sectional views of main portions of the solid-state imaging device which is the semiconductor device of the eighth embodiment of the present disclosure in the order in which the solid-state imaging device is manufactured. Although a method for manufacturing the solid-state imaging device of the second embodiment will be here described as an example, the method can be easily adapted to manufacture the solid-state imaging device of the other embodiments based on the description below.

Initially, as shown in FIG. 11A, an electrode pad 16 (conductor pad) which is made of polysilicon forming a transfer electrode is formed on an insulating film 9 which is formed on a substrate 6 made of, for example, silicon and on which the photodetector 2 such as a photodiode or the like is formed, by photolithography and etching, or the like.

Next, as shown in FIG. 11B, an insulating film 19 which is an oxide film is formed on the substrate 6 to cover the electrode pad 16.

Next, as shown in FIG. 11C, a contact hole is formed in the insulating film 19 by photolithography and etching, or the like. Thereafter, a film of a refractory metal, such as Ti or the like, is grown in the contact hole by sputtering, and tungsten is embedded in the contact hole. The tungsten formed outside the contact hole is removed by etching or the like. As a result, a contact plug 17 is formed.

Next, as shown in FIG. 11D, an electrode pad 15 (conductor pad) made of tungsten which forms a light shield film is formed on the insulating film 19 to contact the contact plug 17. Specifically, a tungsten film is formed by sputtering or chemical vapor deposition (CVD), and is then patterned by photolithography and etching, or the like, to form the electrode pad 15.

Next, as shown in FIG. 12A, an insulating film 20 which is an oxide film is formed on the insulating film 19 by CVD or the like to cover the electrode pad 15, and thereafter, a contact hole is formed in the insulating film 20 by photolithography and etching, or the like. Thereafter, a film of a refractory metal, such as Ti or the like, is grown in the contact hole by sputtering, and tungsten is embedded in the contact hole. The tungsten formed outside the contact hole is removed by etching or the like. As a result, a contact plug 18 is formed.

Next, as shown in FIG. 12B, titanium (Ti) and titanium nitride (TiN) are successively formed by sputtering, and Al is grown, and thereafter, an interconnect 3 and an electrode pad 4 are formed by photolithography and etching, or the like. Note that the interconnect 3 is connected to an output portion in order to apply a drive pulse to the transfer electrode of the photodetector 2 or output a signal.

Next, as shown in FIG. 12C, the substrate 6 is thinned to a thickness of 100-300 nm from the lower surface thereof by chemical mechanical polishing or etching, and thereafter, a through hole 6a through which the lower surface of the electrode pad 16 is exposed is formed by photolithography and etching, or the like.

Next, as shown in FIG. 12D, an insulating film 9 which is an oxide film is formed in the through hole 6a and on the lower surface of the substrate 6 by CVD or the like, and thereafter, only the insulating film 9 on the lower surface of the electrode pad 16 is removed by photolithography and etching, or the like, Ti is sputtered, and Al is grown, thereby forming a through electrode 5. Thereafter, a lower-surface electrode 10 is formed by photolithography and etching, or the like.

Thus, the solid-state imaging device of the second embodiment having a structure which can hinder or prevent the increase in the resistance or the penetration of the surface by the electrode pad can be manufactured.

Note that, typically, an inner-layer lens which is upwardly convex, downwardly convex, or both upwardly and downwardly convex is formed, and a color filter is formed, and thereafter, a top lens is formed, although not shown.

The electrode pad 16 may not be made of the same material as that of the transfer electrode, and may not be formed at the same time when the transfer electrode is formed. The electrode pad 16 may be made of other polysilicon layers or tungsten (W). Similarly, the electrode pad 15 may not be made of the same material as that of the light shield film, and may not be formed at the same time when the light shield film is formed. The electrode pad 15 may be made of other tungsten layers or tungsten silicide.

Moreover, in the first to eighth embodiments, a protective circuit may be formed below the electrode pad 4, below the electrode pad 14 or 15 or the electrode pad 16 or 33, or between the layers, whereby the chip area can be reduced.

### Ninth Embodiment

A method for manufacturing a solid-state imaging device which is a method for manufacturing a semiconductor device according to a ninth embodiment of the present disclosure will be described hereinafter with reference to the drawings.

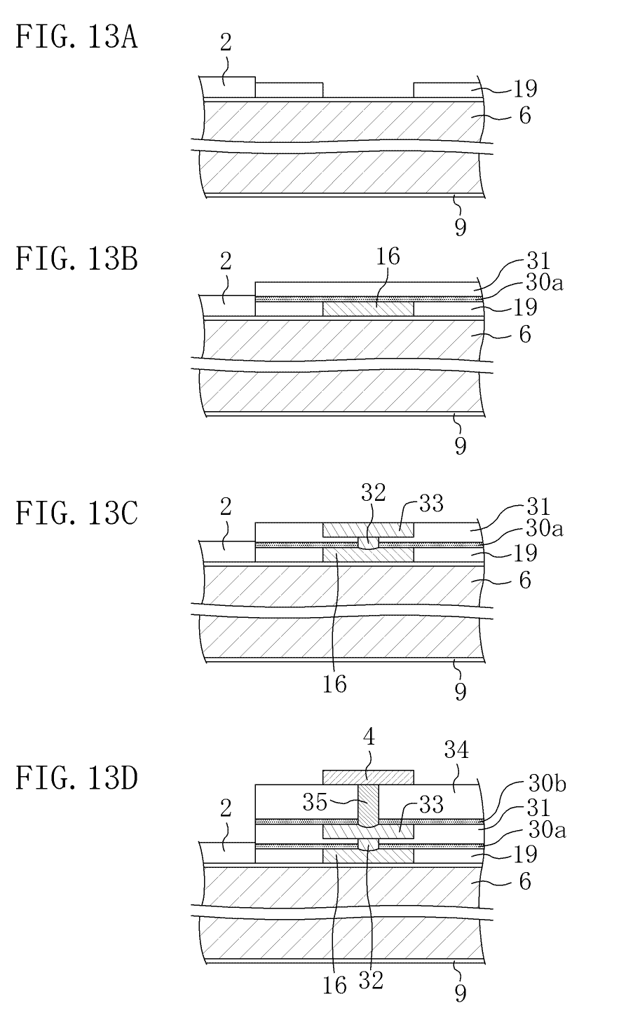

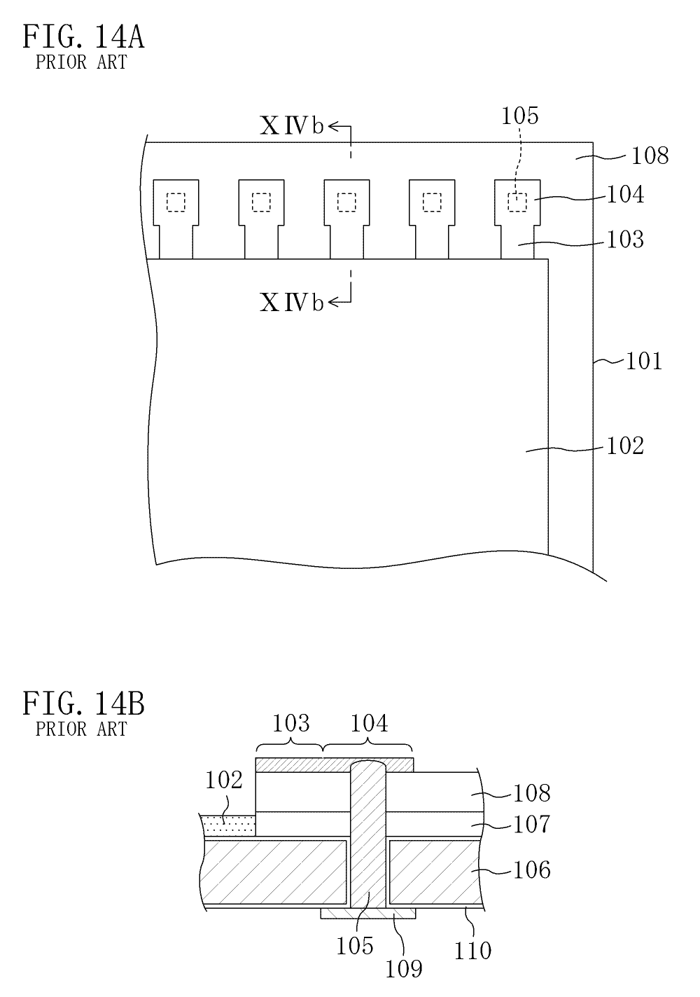

FIGS. 13A-13D are cross-sectional views of main portions of the solid-state imaging device which is the semiconductor device of the ninth embodiment of the present disclosure in the order in which the solid-state imaging device is manufactured.

The solid-state imaging device manufacturing method of this embodiment is different from that of the eighth embodiment in that electrode pads 16 (conductor pads), vias 32, and electrode pads 33 (conductor pads) are made of copper (Cu) as described below.

Initially, as shown in FIG. 13A, an insulating film 19 is formed on an insulating film 9 which is formed on a substrate 6 made of, for example, silicon and on which a photodetector 2 such as a photodiode or the like is formed. The insulating film 19 has an opening through which the insulating film 9 is exposed.

Next, as shown in FIG. 13B, in the opening of the insulating film 19, a film of tantalum (Ta), tantalum nitride (TaN), or the like is grown as a barrier metal, and Cu plating is formed. Thereafter, the Cu or TaN formed on the insulating film outside the opening is removed by CMP to form the electrode pad 16. Next, a nitride (SiN) film 30a is grown on the insulating film 19 to cover the electrode pad 16. Next, an insulating film 31 which is an oxide film is formed on the nitride film 30a by CVD or the like.

Next, as shown in FIG. 13C, an opening for formation of the electrode pad 33 described below is formed in the insulating film 31 and the nitride film 30a, and moreover, a via hole is formed, by dual damascene. Next, in the opening and the via hole, a TaN film is grown and Cu plating is then formed. Thereafter, by removing the Cu or TaN on the surface of the insulating film 31 by CMP, the via 32 and the electrode pad 33 are formed.

Next, as shown in FIG. 13D, a nitride (SiN) film 30b is formed on the insulating film 31 and the electrode pad 33, and thereafter, an insulating film 34 which is an oxide film is grown by CVD or the like. Next, a contact hole is formed in the insulating film 34 and the nitride film 30b by photolithography and etching, or the like, and in the contact hole, a TaN or Ti film is grown, and tungsten is grown. Thereafter, the TaN or Ti and tungsten formed outside the contact hole are removed to form a contact plug 35. Next, Ti and TiN films are successively grown on the insulating film 34 by sputtering to contact the contact plug 35, and thereafter, an Al—Cu film is grown. Thereafter, an electrode pad 4 is formed by photolithography and etching, or the like.

Note that the subsequent steps are similar to those which are described with reference to of FIGS. 12C and 12D in the eighth embodiment. Note that, typically, an inner-layer lens which is upwardly convex, downwardly convex, or both upwardly and downwardly convex is formed, and a color filter is formed, and thereafter, a top lens is formed, although not shown.

Thus, when the electrode pad 16, the via 32, and the electrode pad 33 are made of copper (Cu), a solid-state imaging device having a structure capable of hindering or preventing the increase in the resistance or the penetration of the surface by the electrode pad, and a method for manufacturing the solid-state imaging device can be provided.

As described above, the present disclosure is, for example, useful for an improvement in reliability, manufacturing throughput, image quality, and the like when the sizes of a solid-state imaging device and a package are reduced.

What is claimed is:

1. A semiconductor device comprising:
a through electrode penetrating a semiconductor substrate;
a conductor pad formed on the through electrode and made of a conductor electrically connected to the through electrode; and
an interconnection layer formed on a surface of the semiconductor substrate and electrically connected to the conductor pad.

2. The semiconductor device of claim 1, wherein
the conductor pad is made of one selected from polysilicon, aluminum, metals containing aluminum, copper, copper alloys, refractory metals, and silicides thereof.

3. The semiconductor device of claim 1, wherein
the conductor pad includes a plurality of layers each made of one selected from polysilicon, aluminum, metals containing aluminum, copper, copper alloys, refractory metals, and silicides thereof.

4. The semiconductor device of claim 1, wherein
the interconnection layer and the conductor pad are connected to each other via a first contact plug.

5. The semiconductor device of claim 4, wherein
the interconnection layer includes an electrode pad,
a region of the interconnection layer in which the electrode pad is formed includes a region which a probe for probe testing contacts, and
a region of the interconnection layer in which the electrode pad is not formed includes a region to which the first contact plug is connected.

6. The semiconductor device of claim 1, wherein
the conductor pad includes a plurality of conductor pads electrically connected to each other,
the lowest one of the plurality of conductor pads is electrically connected to the through electrode, and
the uppermost one of the plurality of conductor pads is electrically connected to the interconnection layer.

7. The semiconductor device of claim 4, wherein
the interconnection layer has a larger interconnect width than a diameter of the first contact plug.

8. The semiconductor device of claim 4, wherein
the conductor pad has a larger area as viewed from the top than that of the through electrode.

9. The semiconductor device of claim 5, wherein
of the plurality of conductor pads, adjacent ones partially overlap as viewed from the top and are electrically connected to each other via a second contact plug.

10. The semiconductor device of claim 1, wherein
the through electrode is connected to the conductor pad directly or by the through electrode penetrating the conductor pad.

11. The semiconductor device of claim 1, wherein
a plurality of photodetectors are formed on a surface of the semiconductor substrate.

12. The semiconductor device of claim 1, wherein
the conductor pad is formed in the same layer in which a transfer electrode or an output transistor gate is formed.

13. The semiconductor device of claim 1, wherein
there are a plurality of the through electrodes, and
of the plurality of through electrodes, a distance between a first one connected to an output portion and a second one adjacent to the first one is larger than that between the other ones.

14. The semiconductor device of claim 1, wherein
there are a plurality of the through electrodes, and
of the plurality of through electrodes, an insulating film formed around a first one connected to an output portion has a larger thickness than that of an insulating film formed around each of the other ones.

15. The semiconductor device of claim 1, wherein
there are a plurality of the through electrodes, and
of the plurality of through electrodes, a first one connected to an output portion has a smaller area as viewed from the top than that of each of the other ones.

16. A method for manufacturing a semiconductor device including a photodetector on an upper surface of a semiconductor substrate, comprising the steps of:
(a) forming a conductor pad made of a conductor on the semiconductor substrate;
(b) forming, on the upper surface of the semiconductor substrate, an interconnection layer electrically connected to the conductor pad; and
(c) forming a through electrode penetrating a lower surface of the semiconductor substrate and electrically connected to the conductor pad.

17. The method of claim 16, further comprising the step of:
(d) between steps (a) and (b), forming an insulating film covering the conductor pad, and thereafter, forming a contact plug penetrating the insulating film and electrically connected to the conductor pad,
wherein
step (b) includes forming the interconnection layer including an electrode pad so that the interconnection layer is connected to the contact plug,
a region of the interconnection layer in which the electrode pad is formed includes a region which a probe for probe testing contacts, and
a region of the interconnection layer in which the electrode pad is not formed includes a region to which the contact plug is connected.

18. The method of claim 16, wherein
the through electrode is connected to the conductor pad directly or by the through electrode penetrating the conductor pad.
